(19) United States
(12) Patent Application Publication
(10) Pub. No.: US 2024/0117498 A1
(43) Pub. Date: Apr. 11, 2024

(54) COATED CUTTING TOOL

(71) Applicant: SECO TOOLS AB, Fagersta (SE)

(72) Inventors: Jonas LAURIDSEN, Fagersta (SE); Tommy LARSSON, Fagersta (SE); Jon ANDERSSON, Fagersta (SE); Hindrik ENGSTROM, Fagersta (SE); Oscar ALM, Fagersta (SE)

(21) Appl. No.: 17/767,707

(22) PCT Filed: Oct. 7, 2020
(86) PCT No.: PCT/EP2020/078118

§ 371 Date: Apr. 8, 2022

(30) Foreign Application Priority Data
Oct. 11, 2019 (EP) 19202871.0

(51) Int. Cl. C23C 28/04; B23B 27/14; C23C 14/06; C23C 14/32; C23C 16/34

(52) U.S. Cl. CPC C23C 28/044; B23B 27/148; C23C 14/0641; C23C 14/325; C23C 16/34; B23B 2228/105

(57) ABSTRACT

A coated cutting tool and a method to manufacture, and the use of the same is provided. The coated cutting tool includes of a substrate and a coating including a physical vapor deposition (PVD) deposited Ti,Al-based nitride layer having a thickness of at least 1.0 μm. The PVD deposited Ti,Al-based nitride layer has at least one layer of TiAlN. The coating further includes a CVD deposited layer of TiN located between the substrate and the PVD deposited Ti,Al-based nitride layer. The CVD deposited layer of TiN is in contact with both the substrate and the PVD deposited Ti,Al-based nitride layer. The method for manufacturing a coated cutting tool includes growing a TiN layer by CVD on the substrate, and growing a Ti,Al-based nitride layer by PVD on the TiN layer.

### TECHNICAL FIELD

The present disclosure relates to a coated cutting tool and a method for manufacturing the same.

### BACKGROUND

Since the mid 1980's, efforts have been made to improve the properties, for example, wear resistance and hence the performance of cutting tool coatings. At that time, the common practice was to coat cutting tools with titanium nitride (TiN). However, due to its relatively poor oxidation resistance at elevated temperatures, alloying aluminium (Al) in the TiN coating was suggested and implemented with good results in the mid-1980's.

Today (Ti,Al)N based coatings are among the most common hard and protective coating materials used in metal cutting applications. The cubic, B1, structure of (Ti,Al)N, as a monolith layer and/or part of a laminated coating structure, combine attractive mechanical properties, such as high hardness and improved temperature and oxidation resistance providing good performance in metal machining applications. The technological benefits of (Ti,Al)N and its excellent physical properties, especially at elevated temperatures, is partly explained in terms of a spinodal decomposition process during which cubic (Ti,Al)N decompose isostructurally into coherent cubic c-AlN- and c-TiN-enriched domains. The combination of elastic properties and a lattice mismatch between coherent c-AlN- and c-TiN-enriched domains leads to significant age hardening during which the hardness of (Ti,Al)N thin layers have shown to increase with between 15% and 20%. At further aging, c-AlN transforms into the thermodynamically stable hexagonal, wurtzite B4 structure, h-AlN resulting in a dual phase structure comprising c-TiN and h-AlN with reduced mechanical properties.

Today, industry continuously seeks solutions for economic and high productivity/feed-through manufacturing. To meet these demands there is a need for new materials with advanced properties to improve tool-life during operation.

### SUMMARY

It is an aim of the present disclosure to provide an improved coated cutting tool. This aim is achieved by a device as defined in claim 1 and by the method of claim 12.

The disclosure provides a coated cutting tool consisting of a substrate and a coating. The coating comprises a physical vapor deposition (PVD) deposited titanium aluminium (Ti,Al)-based nitride layer having a thickness of at least 1.0 μm, wherein the PVD deposited Ti,Al-based nitride layer comprises at least one layer of titanium aluminium nitride (TiAlN), and a chemical vapor deposition (CVD) deposited layer of titanium nitride (TiN) located between the substrate and the PVD deposited Ti,Al-based nitride layer, wherein the CVD deposited layer of TiN is in contact with both the substrate and the PVD deposited Ti,Al-based nitride layer. In other words, a coated cutting tool is provided, which has a CVD deposited layer of TiN between the substrate and the PVD deposited Ti,Al-based nitride layer. Tests have shown that the average tool-life of a coated cutting tool with a CVD deposited layer of TiN between the substrate and the PVD deposited Ti,Al-based nitride layer is increased compared to prior art solutions with only a Ti,Al-based nitride layer as coating on the substrate. The CVD deposited layer of TiN improves adherence of the PVD deposited Ti,Al-based nitride layer to the substrate and thus prevents or inhibits abrasion or breakage, flaking off or peeling off the PVD deposited Ti,Al-based nitride layer.

According to some aspects, the thickness of the CVD deposited layer of TiN is between 0.1 and 1.7 μm and preferably between 0.1 and 1.0 μm and even more preferably between 0.1 and 0.7 μm. A thicker layer may increase the risk of thermal cracking. A thinner layer introduces a risk that the CVD layer does not cover the whole intended surface of the substrate.

According to some aspects, the thickness of the PVD deposited Ti,Al-based nitride layer is between 1 and 12 μm and preferably between 2 and 10 μm. The Ti,Al-based nitride layer is used for hardening the surface of the cutting tool. A thickness in the above range provides a hard surface which is preferred in use. Other thicknesses may of course also improve the hardness of the surface but using a lot of material affects the cost of the cutting tool.

According to some aspects, the PVD deposited Ti,Al-based nitride layer is a (Ti₁₋ₓAlₓ)N_{y} layer, wherein 0.1<x<0.8 and 0.6<y<1.1. TiAlN layers are known in the art for providing a good surface to cutting tools.

According to some aspects, the PVD deposited Ti,Al-based nitride layer is a laminated layer having alternating layers of (Ti₁₋ₓAlₓ)N_{y}-layers and (Ti₍₁₋ₗ₎Siₗ)Nₘ-layers, wherein 0.1<x<0.8, 0.7<y<1.1, 0.05<1<0.2 and 0.7<m<1.1. A layer with alternating layers of TiAlN and TiSiN have been shown to provide an improved cutting surface to the cutting tool. The alternating layer is also improved with a CVD deposited layer of TiN between it and the substrate.

According to some aspects, the thickness of the (Ti₍₁₋ₗ₎Siₗ)Nₘ-layers is between 1 and 100 nm and preferably between 5 and 50 nm.

According to some aspects, the PVD deposited Ti,Al-based nitride layer is a laminated layer having alternating layers of (Ti₁₋ₓAlₓ)N_{y}— layers and (Ti₍₁₋ᵣ₋ₛ₎AlᵣCrₛ)Nₜ-layers wherein 0.1<x<0.8, 0.7<y<1.1, 0.5<r<0.75, 0.05<s<0.2 and 0.7<t<1.1. A layer with alternating layers of TiAlN and TiAlCrN have been shown to provide an improved cutting surface to the cutting tool. The alternating layer is also improved with a CVD deposited layer of TiN between it and the substrate.

According to some aspects, the thickness of the (Ti₍₁₋ᵣ₋ₛ₎AlᵣCrₛ)Nₜ-layers is between 1 and 100 nm and preferably between 5 and 50 nm.

According to some aspects, the thickness of the (Ti₁₋ₓAlₓ)N_{y}-layers is between 1 and 100 nm and preferably between 5 and 50 nm.

According to some aspects, one layer of TiAlN of the PVD deposited Ti,Al-based nitride layer is arranged in contact with the CVD deposited layer of TiN. In the cases where the PVD deposited Ti,Al-based nitride layer is a laminated layer with alternating layers, it may be beneficial that the part of the Ti,Al-based nitride layer that is in contact with the CVD deposited layer of TiN is made of TiAlN.

According to some aspects, the substrate is selected from the group comprising cemented carbide, cermet, ceramic, high speed steel, polycrystalline diamond, and polycrystalline cubic boron nitride, or any combination thereof. Such substrates are known to be well working substrates for coated cutting tools.

The disclosure provides a method for manufacturing a coated cutting tool according to any of the aspects described above by applying CVD techniques and PVD techniques, preferably cathodic arc evaporation, the method comprises growing a TiN layer by CVD on the substrate, and growing a Ti,Al-based nitride layer by PVD on the TiN layer. The method provides a reliable manner to manufacture the above coated cutting tool.

According to some aspects, the Ti,Al-based nitride layer (3a) is a TiAlN layer and growing the TiAlN layer by PVD on the TiN layer comprises using cathodic arc evaporation from a composite or alloyed Ti,Al cathode, applying an evaporation current between 50 A and 200 A, using a reactive gas atmosphere comprising N₂, at a total gas pressure between 1.0 Pa and 8.0 Pa, applying a negative substrate bias between 20 V and 300 V, and applying a deposition temperature between 200° C. and 800° C., preferably between 300° C. and 600° C.

According to some aspects, the TiN layer is grown using CVD, preferably moderate temperature CVD.

According to some aspects, the TiN layer is grown at a temperature of at least 825° C.

According to some aspects, the TiN layer is grown at a temperature between 825° C. and 950° C.

According to some aspects, the TiN layer is grown at a temperature between 825° C. and 900° C.

The disclosure provides a use of a coated cutting tool according to any of the aspects described above for machining at cutting speeds of 50 to 400 m/min, preferably 75 to 300 m/min, with an average feed per tooth, in the case of milling, of 0.01 to 0.5 mm, preferably 0.01 to 0.4 mm, whereby the feed per tooth depends on the cutting speed and an insert geometry.

### BRIEF DESCRIPTION OF THE DRAWINGS

The invention will now be explained more closely by the description of different aspects of the invention and with reference to the appended figures.

FIG. 1 shows an example of layers of a coated cutting tool.

FIG. 2 shows another example of layers of a coated cutting tool where one layer comprises a laminated alternating layer.

FIG. 3 shows an SEM image of an example coating on a substrate.

FIG. 4 shows a block diagram of an example method of manufacturing the coated cutting tool.

### DETAILED DESCRIPTION

Aspects of the present disclosure will be described more fully hereinafter with reference to the accompanying drawings. The device and method disclosed herein can, however, be realized in many different forms and should not be construed as being limited to the aspects set forth herein. Like numbers in the drawings refer to like elements throughout.

The terminology used herein is for the purpose of describing particular aspects of the disclosure only and is not intended to limit the invention. As used herein, the singular forms “a”, “an” and “the” are intended to include the plural forms as well, unless the context clearly indicates otherwise.

Unless otherwise defined, all terms (including technical and scientific terms) used herein have the same meaning as commonly understood by one of ordinary skill in the art to which this disclosure belongs.

The term “cutting tool”, as used herein, is intended to denote cutting tools suitable for cutting by chip removal, such as turning, milling or drilling. Examples of cutting tools are indexable cutting inserts, solid drills or end mills.

The term “substrate” as denoted herein should be understood as a body onto which a coating is deposited. Common for cutting tools is that this substrate, for example, a cutting tool insert, may be a solid body or a body comprising a backing body onto which an additional material is placed, either over the cutting edge on the rake face, a so called tipped body, or such that it covers the full rake, a so called full face body. The tipped or full-face solutions are frequently used in cutting technologies based on polycrystalline diamond or polycrystalline cubic boron nitride materials.

It should be noted that when using the term “thickness” to discuss a thickness of a layer, it is the average thickness of the discussed layer that is meant. The below discussed layers may have a varying thickness over the surface where it is arranged and thus, the term “thickness” here means the “average thickness” of the layer over the surface.

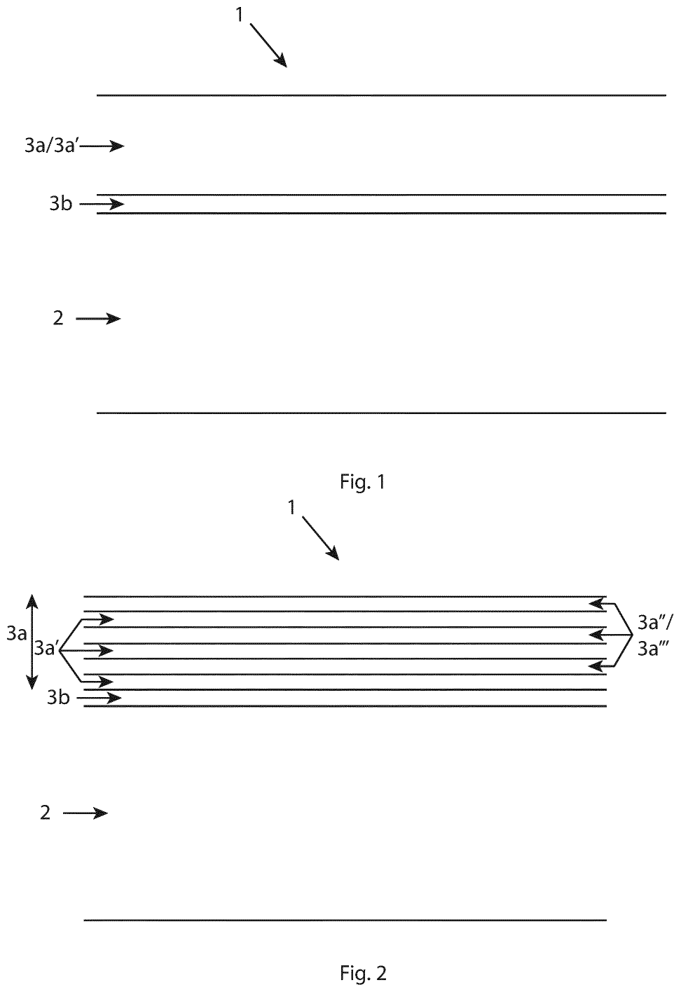

FIG. 1 shows an example of layers of a coated cutting tool. The disclosure provides a coated cutting tool 1 consisting of a substrate 2 and a coating 3. The coating 3 comprises or consists of a physical vapor deposition (PVD) deposited titanium aluminium (Ti,Al)-based nitride layer 3a having a thickness of at least 1.0 μm. The PVD deposited Ti,Al-based nitride layer comprises at least one layer 3a′ of titanium aluminium nitride (TiAlN).

The thickness of the PVD deposited Ti,Al-based nitride layer 3a may, for example, be between 1 and 12 μm and preferably between 2 and 10 μm. The limiting numbers 1 and 12 and 2 and 10 are included in the range. The Ti,Al-based nitride layer is used for hardening the surface and limiting the wear of the cutting tool. A thickness in the above defined ranges provides a hard and wear resistant surface, which improves use of a tool. Other thicknesses may of course also affect the hardness of the surface but using higher thicknesses may result in brittleness.

The PVD deposited Ti,Al-based nitride layer 3a may, for example, be a (Ti₁₋ₓAlₓ)N_{y} layer 3a′, wherein 0.1<x<0.8, preferably 0.4<x<0.7, and 0.6<y<1.1. The x here giving the ratio between Al to Al+Ti and y giving the ratio of N to the metals. TiAlN layers are known in the art for providing improved surfaces to cutting tools.

FIG. 2 shows an example of layers of a coated cutting tool 1, where the PVD deposited Ti,Al-based nitride layer 3a comprises or consists of a laminated alternating layer. The PVD deposited Ti,Al-based nitride layer 3a may thus be a laminated structure consisting of alternating A and B layers: AM/A/B/A/B/ . . . The layer A may be, for example, (Ti₁₋ₓAlₓ)N_{y}-layers 3a′ and the B layers may be, for example, (Ti₍₁₋ₗ₎Siₗ)Nₘ-layers 3a″ or (Ti₍₁₋ᵣ₋ₛ₎AlᵣCrₛ)Nₜ-layers 3a′″.

Thus, the PVD deposited Ti,Al-based nitride layer 3a may be a laminated layer having alternating layers of (Ti₁₋ₓAlₓ)N_{y}-layers 3a′ and (Ti₍₁₋ₗ₎Siₗ)Nₘ-layers 3a″, wherein 0.1<x<0.7 and preferably 0.4<x<0.7, 0.7<y<1.1, 0.05<1<0.2 and 0.7<m<1.1. A layer with alternating layers of TiAlN and TiSiN have shown to provide an improved cutting surface to the cutting tool. The alternating layer is also improved with a CVD deposited layer of TiN between it and the substrate. The thickness of the (Ti₍₁₋ₗ₎Siₗ)Nₘ-layers 3a″ may be between 1 and 100 nm and preferably between 5 and 50 nm, whereby the limiting numbers 1, 100, 5 and 50 are included in the range.

An alternative is that the B layers may comprise (Ti₍₁₋ₖ₋ₗ₎AlₖSiₗ)Nₘ-layers 3a″, wherein 0.2<k<0.7, 0.05<l<0.3 and 0.7<m<1.1. The thickness being the same as the (Ti₍₁₋ₗ₎Siₗ)Nₘ-layers 3a″.

The PVD deposited Ti,Al-based nitride layer 3a may be a laminated layer having alternating layers of (Ti₁₋ₓAlₓ)N_{y}-layers 3a′ and (Ti₍₁₋ᵣ₋ₛ₎AlᵣCrₛ)Nₜ-layers 3a′″ wherein 0.1<x<0.7, 0.7<y<1.1, 0.5<r<0.75, 0.05<s<0.2 and 0.7<t<1.1. Cr here being chromium. A layer with alternating layers of TiAlN and TiAlCrN has shown to provide an improved cutting surface to the cutting tool. The alternating layer is also improved with a CVD deposited layer of TiN between it and the substrate. The thickness of the (Ti₍₁₋ᵣ₋ₛ₎AlᵣCrₛ)Nₜ-layers 3a′″ may be between 1 and 100 nm and preferably between 5 and 50 nm, whereby the limiting numbers 1, 100, 5 and 50 are included in the range.

For the laminated layers, the thickness of the (Ti₁₋ₓAlₓ)N_{y}-layers 3a′ may be between 1 and 100 nm and preferably between 5 and 50 nm, whereby the limiting numbers 1, 100, 5 and 50 are included in the range.

For the laminated layers above, the total thickness of the layers is, for example, between 1 and 12 μm and preferably between 2 and 10 μm.

One layer of TiAlN 3a′ of the PVD deposited Ti,Al-based nitride layer 3a may be arranged in contact with the CVD deposited layer of TiN 3b. In the cases where the PVD deposited Ti,Al-based nitride layer (3a) is a laminated layer with alternating layers, it may be beneficial that the part of the Ti,Al-based nitride layer that is in contact with the CVD deposited layer of TiN is made of TiAlN.

An alternative to the above laminated layers may be that a TiAlN layer is first deposited on the CVD deposited layer of TiN and then any of the above discussed laminated layers may be deposited on the TiAlN layer. For example, a TiAlN layer with a thickness of between 0.5 and 1 μm is first deposited on the CVD deposited layer of TiN and then a multilayer of TiAlN/TiSiN according to above is deposited on the TiAlN layer with a thickness of between 2 and 10 μm.

The coating 3 further comprises a chemical vapor deposition (CVD) deposited layer (3b) of titanium nitride (TiN) located between the substrate 2 and the PVD deposited Ti,Al-based nitride layer 3a. In other words, the CVD deposited layer of TiN is arranged directly on top of the substrate and the PVD deposited Ti,Al-based nitride layer 3a is arranged directly on top of the CVD deposited layer of TiN.

As can be seen in FIGS. 1 and 2, the CVD deposited layer of TiN 3b is in contact with both the substrate 2 and the PVD deposited Ti,Al-based nitride layer 3a. In other words, a coated cutting tool is provided, where there is a CVD deposited layer of TiN between the substrate and the PVD deposited Ti,Al-based nitride layer.

Tests have shown that the average tool life of a coated cutting tool with a CVD deposited layer of TiN between the substrate and the PVD deposited Ti,Al-based nitride layer is increased compared to prior art solutions with only a Ti,Al-based nitride layer as coating on the substrate. The CVD deposited layer of TiN improves adherence of the PVD deposited Ti,Al-based nitride layer to the substrate and thus prevents or inhibits abrasion or breakage, flaking off or peeling off the PVD deposited Ti,Al-based nitride layer. The CVD-layer provides a more homogenous surface covering, and filling cracks and cavities on the substrate surface for the PVD coating to nucleate on, compared to, for example, a hard metal substrate heterogenous surface consisting of tungsten carbide, WC, and cobalt, Co, surfaces with different properties.

It should be noted that the coating comprises or consists of the herein defined PVD deposited Ti,Al-based nitride layer 3a and the CVD deposited layer of TiN 3b.

It should also be noted that the CVD deposited layer of TiN 3b can include unavoidable traces or contaminants of carbon (C) and/or oxygen (O) and/or cobalt (Co). C and/or O and/or Co can for example be present as contaminants, originating for example in the underlying substrate or other sources. In other words, there may be C and/or O and/or Co present in the TiN layer at small amounts of a total concentration of 0 to 5 at %.

The PVD deposited Ti,Al-based nitride layer 3a can include unavoidable traces or contaminants of carbon (C) and/or oxygen (O). C and/or O can for example be present as contaminants, originating for example in the underlying coating material or other sources. In other words, there may be C and/or O present in the Ti,Al-based nitride layer 3a at small amounts of a total concentration of 0 to 2 at %.

The PVD deposited Ti,Al-based nitride layer 3a may further comprise one or more further metal elements, Me, in small amounts not substantially altering the properties of the layer. For example, resulting from impurities in the targets used in the PVD deposition process. For example, less than 1 at %, or less than 0.5 at %, or less than 0.3 at %, or less than 0.1 at %, of the sum of Ti+Al+Si+Me in the coating. The metal elements, Me, is, for example, one or more of Zr, Hf, V, Nb, Ta, Mo, Fe, and W.

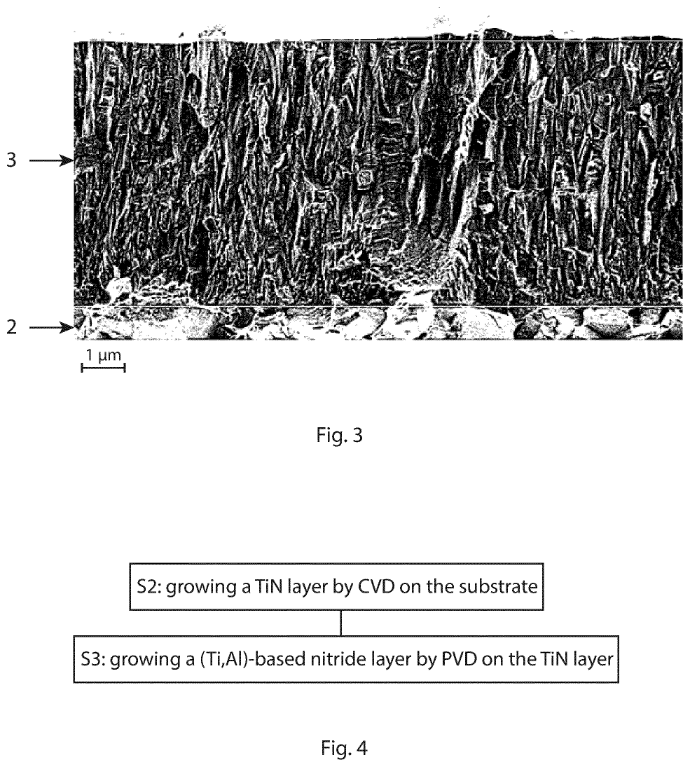

FIG. 3 shows an SEM image of an example coating 3 on a substrate 2.

The thickness of the CVD deposited layer of TiN 3b may be between 0.1 and 1.7 μm and preferably between 0.1 and 1.0 μm and even more preferably between 0.1 and 0.7 μm, whereby numbers 0.1, 1.7, 1.0 and 0.7 are included in the range. A thicker layer may increase the risk of thermal cracking. A thinner layer introduces a risk that the CVD layer does not cover the whole intended surface of the substrate.

The substrate 2 may be selected from the group comprising or consisting of cemented carbide, cermet, ceramic, high speed steel, polycrystalline diamond (PCD), and polycrystalline cubic boron nitride (PCBN), or any combination thereof. Such substrates are known to be well working substrates for coated cutting tools. Preferably, the substrate comprises cemented carbide, preferably of cemented carbide consisting of 4 to 14 wt-% Co, optionally 0.3-10 wt-% cubic carbides, nitrides or carbonitrides of the metals from groups IVb, Vb and Vlb of the periodic table, preferably Ti, Nb, Ta or combinations thereof, and balance WC.

The substrate may consist of cemented carbide comprising a binder phase enriched surface zone having a thickness of 5 to 30 μm, preferably 10 to 25 μm, from the substrate surface. The binder phase enriched surface zone having a Co content that is at least 1.5 times higher than in the core of the substrate and having a content of cubic carbides that is less than 0.5 times the content of cubic carbides in the core of the substrate. Preferably, the binder phase enriched surface zone of the cemented carbide substrate is essentially free from cubic carbides. Providing a binder phase enriched surface zone enhances toughness of the substrate and may thus widen the application range of the coated cutting tool.

The substrate may, according to some aspects, comprise cemented carbide consisting of 4 to 14 wt-% Co, Cr in a content of from 3.5% to 9% of the cobalt content, and balance WC.

FIG. 4 shows a block diagram of an example method of manufacturing the coated cutting tool. The method for manufacturing a coated cutting tool 1 as described above comprises applying CVD techniques and PVD techniques, preferably cathodic arc evaporation. The method comprise growing S2 a TiN layer 3b by CVD on the substrate 2, and growing S3 a Ti,Al-based nitride layer 3a by PVD on the TiN layer 3b. The method provides a reliable way to manufacture the above coated cutting tool. The growing S2 a TiN layer 3b by CVD on the substrate 2 and the growing S3 a Ti,Al-based nitride layer 3a by PVD on the TiN layer 3b comprises growing directly on the substrate 2 and the TiN layer, respectively.

Before growing S2 the TiN layer 3b or before growing S3 the Ti,Al-based nitride layer 3a, the cutting tool may be subject to cleaning S1 according to standard PVD process procedures, for example, by washing.

An alternative to using cathodic arc evaporation is, for the PVD layer, for example, using sputtering. An alternative to using conventional CVD is, for the CVD layer, for example, to use Atomic Layer Deposition, ALD.

The Ti,Al-based nitride layer (3a) may be a TiAlN layer and then growing the TiAlN layer by PVD on the TiN layer 3b may comprise using cathodic arc evaporation from composite or alloyed (Ti,Al) cathodes, applying an evaporation current between 50 A and 200 A, using a reactive gas atmosphere comprising N₂, at a total gas pressure between 1.0 Pa and 8.0 Pa, applying a negative substrate bias between 20 V and 300 V, and applying a deposition temperature between 200° C. and 800° C., preferably between 300° C. and 600° C. The reactive gas atmosphere may comprise pure N₂, or mixed N₂ and argon (Ar) gases.

In the case when the PVD deposited Ti,Al-based nitride layer 3a is a laminated layer comprising (Ti₁₋ₓAlₓ)N_{y}-layers 3a′ and (Ti₍₁₋ᵣ₋ₛ₎AlᵣCrₛ)Nₜ-layers, the growing S3 a Ti,Al-based nitride layer 3a by PVD may comprise growth of TiAlN and TiAlCrN layers by using cathodic arc evaporation from composite or alloyed (Ti,Al) and (Ti,Al,Cr) cathodes, respectively, applying an evaporation current between 50 A and 200 A, using a reactive gas atmosphere comprising pure N₂ or mixed N₂ and, e.g., Ar gases at a total gas pressure between 1.0 Pa and 8.0 Pa, 1.0 Pa and 5.0 Pa, more preferably between 2.0 Pa and 5.0 Pa, most preferably between 3.0 Pa and 5.0 Pa, applying a negative substrate bias between 20 V and 300 V, preferably between 20 V and 150 V, most preferably between 20 V and 100 V, and applying a deposition temperature between 200° C. and 800° C., preferably between 300° C. and 600° C. The laminated layer structure may be produced by 1-fold, 2-fold, or 3-fold substrate rotation during deposition.

In the case when the PVD deposited Ti,Al-based nitride layer 3a is alternating layers of (Ti₁₋ₓ Alₓ)N_{y}-layers 3a′ and (Ti₍₁₋ₗ₎Siₗ)Nₘ-layers 3a″, the growing S3 a Ti,Al-based nitride layer 3a by PVD may comprise growth of TiAlN and TiSiN layers by using cathodic arc evaporation from composite or alloyed (Ti,Al) and (Ti,Si) cathodes, respectively, applying an evaporation current between 50 A and 200 A, using a reactive gas atmosphere comprising pure N₂ or mixed N₂ and, e.g., Ar gases at a total gas pressure between 1.0 Pa and 8.0 Pa, 1.0 Pa and 5.0 Pa, more preferably between 2.0 Pa and 5.0 Pa, most preferably between 3.0 Pa and 5.0 Pa, applying a negative substrate bias between 20 V and 300 V, preferably between 20 V and 150 V, most preferably between 20 V and 100 V, and applying a deposition temperature between 200° C. and 800° C., preferably between 300° C. and 600° C. The laminated layer structure may be produced by 1-fold, 2-fold, or 3-fold substrate rotation during deposition.

The TiN layer may be grown using CVD, preferably moderate temperature CVD.

The pressure when growing the TiN layer is, for example, between 60 and 700 mbar.

The temperature when growing the TiN layer is, for example, at least 825° C. According to some aspects, the TiN layer is grown at a temperature between 825° C. and 950° C., preferably between 825° C. and 900° C.

The reactive gas concentrations are, for example, in the ranges of:
between 40 vol % and 80 vol %, and preferably between 65 vol % and 75 vol % of H₂,
between 20 vol % and 80 vol %, and preferably between 22 vol % and 33 vol % of N₂,
between 0 vol % and 5 vol %, and preferably between 1 vol % and 2 vol % of HCl,
between 0.6 vol % and 2.8 vol %, and preferably between 1.3 vol % and 2.3 vol % of TiCl₄,

An alternative to using N₂ gas is to use ammonia, NH₃.

As an example of a grown TiN layer, the following sample has been made. The substrate was coated with a thin, approximately 0.4 μm, TiN-layer employing the well-known moderate temperature CVD, MTCVD, technique using TiCl₄, N₂, HCl and H₂ at 860° C. The details of the TiN deposition are shown in Table 1.

TABLE 1
MTCVD of TiN

| MT CVD of | | | | | |
|---|---|---|---|---|---|
| TiN and TiCN | Pressure | H₂ | N₂ | HCl | TiCl₄ |
| (860° C.): | [mbar] | [vol %] | [vol %] | [vol %] | [vol %] |
| TiN | 600 | 69.2 | 27.7 | 1.4 | 1.7 |

The disclosure provides a use of a coated cutting tool 1 as defined anywhere above for machining at cutting speeds of 50 to 400 m/min, preferably 75 to 300 m/min, with an average feed per tooth, in the case of milling, of 0.01 to 0.5 mm, preferably 0.01 to 0.4 mm, whereby the feed per tooth depends on the cutting speed and an insert geometry.

By combining the above described CVD deposited layer of TiN and a PVD deposited Ti,Al-based nitride layer on top of a substrate, improved coating performance with respect to tool lifetime is achieved, compared to a PVD deposited Ti,Al-based nitride layer on top of a substrate without the CVD deposited layer of TiN.

The following are two tests of coated cutting tools according to the disclosure as compared to a prior art coated cutting tool. Cemented carbide substrates of geometry XOMX120408TR-M12 for milling were manufactured and having the composition of 10.2 wt-% Co, 1.35 wt-% tantalum, Ta, 0.15 wt-% niobium, Nb, and balance WC. The cemented carbide substrates where used for both of the tests below. In the tests, the average tool lifetime of Sample 1 and 3 having a coated cutting tool comprising a substrate coated with a CVD deposited layer of TiN coated with PVD deposited TiAlN is compared to that of Sample 2 and 4 having a coated cutting tool comprising a substrate with PVD deposited TiAlN. The CVD deposited layer of TiN was manufactured according to the specifications of table 1 and the associated text.

The PVD deposited TiAlN layer for samples 1-4 was manufactured using cathodic arc evaporation from powder metallurgically produced Ti_{0.45}Al_{0.55} cathodes of 100 mm diameter, applying an evaporation current of 150 A, using a reactive gas atmosphere comprising N₂, at a total gas pressure of 4.5 Pa, applying a negative substrate bias of 30 V, and applying a deposition temperature of 500° C. The reactive gas atmosphere was pure N₂. The TiAlN layer was deposited to a layer thickness of 6 μm.

Test 1
Dry milling (without coolant)
Tool geometry: XOMX120408TR-M12

| | |
|---|---|
| Diameter of cutter | D = 63 mm |
| Width of cut | Aₑ = 50 mm |
| Feed per tooth | F_{z} = 0.2 mm/tooth |
| Depth of cut | Aₚ = 3 mm |
| Cutting speed | V_{c} = 250 m/min |

Number of edges evaluated per sample: 2
Workpiece material: 42CrMo4; normalized condition

The tests were terminated when the flank wear reached a maximum value of 0.4 mm.

TABLE 2
Result of test 1

| Sample | Coating | Average tool life (min) |
|---|---|---|
| 1 | CVD TiN + PVD TiAlN | 36.7 |
| 2 | PVD TiAlN | 22.5 |

As can be seen in Table 2, the average tool life increases significantly in dry milling applications when the CVD deposited layer of TiN is used between the substrate and the PVD deposited TiAlN. The average tool life increases with 63% for a coating with a CVD deposited layer of TiN between the substrate and the PVD deposited TiAlN layer.

Test 2
Wet milling (coolant used)
Tool geometry: XOMX120408TR-M12

| | |
|---|---|
| Diameter of cutter | D = 63 mm |
| Width of cut | Aₑ = 50 mm |
| Feed per tooth | F_{z} = 0.2 mm/tooth |
| Depth of cut | Aₚ = 3 mm |
| Cutting speed | V_{c} = 250 m/min |

Number of edges evaluated per sample: 2
Workpiece material: 42CrMo4; normalized condition

The tests were terminated when the flank wear reached a maximum value of 0.4 mm.

TABLE 3
Result of test 2

| Sample | Coating | Average tool life (min) |
|---|---|---|
| 3 | CVD TiN + PVD TiAlN | 12.5 |
| 4 | PVD TiAlN | 7.5 |

As can be seen in Table 3, the average tool life increases significantly in wet milling applications when the CVD deposited layer of TiN is used between the substrate and the PVD deposited TiAlN. The average tool life increases with 66% for a coating with a CVD deposited layer of TiN between the substrate and the PVD deposited TiAlN layer.

The present disclosure is not limited to the aspects disclosed but may be varied and modified within the scope of the following claims.

### REFERENCES

1. Coated cuttning tool
2. Substrate
3. Coating
   a. PVD deposited Ti,Al-based nitride layer
      a′. TiAlN layer
      a″. TiSiN layer
      a′″. TiAlCrN layer
   b. CVD deposited layer of TiN

1. A coated cutting tool comprising:
a substrate; and
a coating, wherein the coating includes:
a physical vapor deposition (PVD) deposited titanium aluminium (Ti,Al)-based nitride layer having a thickness of at least 1.0 μm, wherein the PVD deposited Ti,Al-based nitride layer includes at least one layer of titanium aluminium nitride (TiAlN), and
a chemical vapor deposition (CVD) deposited layer of titanium nitride (TiN) located between the substrate and the PVD deposited Ti,Al-based nitride layer, wherein the CVD deposited layer of TiN is in contact with both the substrate and the PVD deposited Ti,Al-based nitride layer.

2. The coated cutting tool according to claim 1, wherein a thickness of the CVD deposited layer of TiN is between 0.1 and 1.7 μm.

3. The coated cutting tool according to claim 1, wherein the thickness of the PVD deposited Ti,Al-based nitride layer is between 1 and 12 μm.

4. The coated cutting tool according to claim 1, wherein the PVD deposited Ti,Al-based nitride layer is a (Ti₁₋ₓAlₓ)N_{y} layer, wherein 0.1<x<0.8 and 0.6<y<1.1.

5. The coated cutting tool according to claim 1, wherein the PVD deposited Ti,Al-based nitride layer is a laminated layer having alternating layers of (Ti₁₋ₓAlₓ)N_{y}-layers and (Ti₍₁₋ₗ₎Siₗ)Nₘ-layers, wherein 0.1<x<0.8, 0.7<y<1.1, 0.05<l<0.2 and 0.7<m<1.1.

6. The coated cutting tool according to claim 5, wherein the thickness of the (Ti₍₁₋ₗ₎Siₗ)Nₘ-layers is between 1 and 100 nm.

7. The coated cutting tool according to claim 1, wherein the PVD deposited Ti,Al-based nitride layer is a laminated layer having alternating layers of (Ti₁₋ₓAlₓ)N_{y}-layers and (Ti₍₁₋ᵣ₋ₛ₎AlᵣCrₛ)Nₜ-layers wherein 0.1<x<0.8, 0.7<y<1.1, 0.5<r<0.75, 0.05<s<0.2 and 0.7<t<1.1.

8. The coated cutting tool according to claim 7, wherein a thickness of the (Ti₍₁₋ᵣ₋ₛ₎AlᵣCrₛ)Nₜ-layers is between 1 and 100 nm and.

9. The coated cutting tool according to claim 5, wherein a thickness of the (Ti₁₋ₓAlₓ)N_{y}-layers is between 1 and 100 nm.

10. The coated cutting tool according to claim 5, wherein one layer of TiAlN of the PVD deposited Ti,Al-based nitride layer is arranged in contact with the CVD deposited layer of TiN.

11. The coated cutting tool according to claim 1, wherein the substrate is selected from the group comprising cemented carbide, cermet, ceramic, high speed steel, polycrystalline diamond, and polycrystalline cubic boron nitride, or any combination thereof.

12. A method for manufacturing a coated cutting tool according to claim 1 by applying CVD techniques and PVD techniques, the method comprising:
growing a TiN layer by CVD on the substrate; and
growing a Ti,Al-based nitride layer by PVD on the TiN layer.

13. The method according to claim 12, wherein the Ti,Al-based nitride layer is a TiAlN layer and growing the TiAlN layer by PVD on the TiN layer includes using cathodic arc evaporation from composite or alloyed (Ti,Al) cathodes, applying an evaporation current between 50 A and 200 A, using a reactive gas atmosphere including N₂, at a total gas pressure between 1.0 Pa and 8.0 Pa, applying a negative substrate bias between 20 V and 300 V, and applying a deposition temperature between 200° C. and 800° C.

14. The method according to claim 12 or 13, wherein the TiN layer is grown using CVD.

15. The method according to claim 14, wherein the TiN layer is grown at a temperature between 825° C. and 900° C.

16. Use A use of a coated cutting tool according to claim 1 for machining at cutting speeds of 50 to 400 m/min, with an average feed per tooth, in the case of milling, of 0.01 to 0.5 mm, whereby the feed per tooth depends on the cutting speed and an insert geometry.

17. The method according to claim 14, wherein the TiN layer is grown using moderate temperature CVD
